(19) United States
(12) Patent Application Publication
(10) Pub. No.: US 2010/0240174 A1
(43) Pub. Date: Sep. 23, 2010

(54) Via Using Zn or Zn Alloys and Its Making Method, 3D Chip Stack Packages Using Thereof

(76) Inventors: Jin Yu, Daejeon (KR); Young-Kun Jee, Daejeon (KR)

Correspondence Address: STERNE, KESSLER, GOLDSTEIN & FOX P.L.L.C., 1100 NEW YORK AVENUE, N.W., WASHINGTON, DC, 20005, US

(21) Appl. No.: 12/680,760

(22) PCT Filed: Dec. 4, 2007
(86) PCT No.: PCT/KR07/06233

§ 371 Date: Mar. 30, 2010

(30) Foreign Application Priority Data
Oct. 5, 2007 (KR) 10-2007-0100501

(51) Int. Cl. H01L 21/768; H01L 21/50

(52) U.S. Cl. 438/107; 438/652; 257/E21.585; 257/E21.499

(57) ABSTRACT

Disclosed are via, a method for formation of via using zinc and zinc alloys, and a process for fabrication of three-dimensional multiple chip stack packages by using the same. In lamination of three-dimensional chips, the chips with reduced defects are rapidly formed by the steps of: punching each of the chips to form a via hole used for a circuit wiring between the chips; depositing a seed layer on an inside of the via hole; forming a plated layer inside the via hole by using Zn and Zn alloys through an electroplating process; removing oxide film from surface of the plated layer; and heat treating the via hole at a temperature of more than melting point of the Zn and Zn alloys. Particularly, the chip having Zn via formed according to the present invention has an advantage of simultaneously overcoming problems in establishment of processing parameters caused by Cu via (e.g., plating mode, current density, influence of additives, pore formation, etc.), problems in successive processes caused by Sn (and other low melting point metals) via (e.g., soldering, chip stack, etc.) and difficulty in mechanical reliability of the process. Additionally, when stacking multiple chips with various functions in the three-dimensional chip stack package, the package can be simply fabricated by controlling contents of constitutional elements in Zn alloy via which has specific thermal properties (such as melting point, thermal expansion coefficient, etc.) suitable for processing temperature of each of the chips.

### TECHNICAL FIELD

The present invention relates to formation of via using zinc (Zn) and Zn alloys and, more particularly, to a method for formation of via using Zn and Zn alloys which deposits Zn and Zn alloys on inner portion of a via hole by an electroplating process, heat treats the deposited via hole to form a chip having the via with reduced defects, and laminates multiple chips in sequence on a top portion of a bottom metal layer of a substrate, or otherwise, laminates a package on a top portion of a bottom metal layer of a substrate after forming the package by laminating at least one chip; via formed by the same; and a process for fabrication of three-dimensional multiple chip stack packages using the chips formed as described above.

### BACKGROUND ART

For chip stack packages commonly available in the related arts, separate chips are wire bonded on a substrate comprising input and output pads. These packages need long length of wires and large area for the wire bonding, and thus, have restrictions in reduction of high frequency properties and production of compact packages.

Specific techniques for fabrication of chip stack packages have been developed to solve the problems described above, which punch each of chips to form a via hole used for fabrication of a circuit wiring between the chips laminated on a substrate and fill the via holes with copper material by an electroplating process.

However, since formation of via using Cu electroplating process is under a considerable influence of compositions of electroplating solutions, species and contents of additives, or current mode and density, etc., the via formation method is difficult to define processing conditions for formation of Cu via without defects (such as pores) as diameter of a via is decreased and aspect ratio thereof is increased and, in addition, the method has a problem of longer time required for forming via.

Additionally, in case of using tin (Sn) instead of Cu, the melting point of Sn in a process for filling via holes with molten Sn is so low as to melt Sn via during further processes of semiconductor chips production by reflowing the molten Sn after initially plating the via holes sufficient to prevent the same from being clogged, thereby causing a problem of reduced reliabilities in mechanical and processing aspects of the semiconductor production.

### DISCLOSURE OF INVENTION

### Technical Problem

Accordingly, the present invention is directed to solve the problem described above in regard to conventional methods and an object of the present invention is to provide a method for formation of via using Zn and Zn alloys which includes depositing Zn and Zn alloys on inner portion of a via hole sufficient to prevent the via hole from being clogged by an electroplating process, and heat treating the deposited via hole at a temperature of more than the melting point of Zn and Zn alloys to allow the molten Zn and Zn alloys to flow into the via hole so as to rapidly fill the via hole without defects, thereby overcoming problems caused by using Cu and Sn and improving reliability in manufacturing chip packages. Another object of the present invention is to provide via formed by the above method according to the present invention. A still further object of the present invention is to provide a process for fabrication of three-dimensional multiple chip stack packages using chips having the via formed by the present invention.

### Technical Solution

In order to accomplish the above objects, with regard to via formed using Zn and Zn alloys, formation thereof and a process for fabrication of a three-dimensional multiple chip stack package according to the present invention, there is provided a method for formation of via with reduced bonds by forming via holes in chips to fabricate a circuit wiring between the chips, electroplating inner portions of the via holes with Zn and Zn alloys to prevent the same from being clogged, and heat treating the plated via holes.

The via formation method using Zn and Zn alloys according to the present invention preferably comprises the step of forming a seed layer inside each of via holes and a further step of forming a plated layer with Zn and Zn alloys on top of the seed layer.

This method further comprises the step of heat treating the plated layer.

The seed layer is preferably deposited with at least one selected from a metal group consisting of gold (Au), nickel (Ni), copper (Cu), platinum (Pt), silver (Ag) and zinc (Zn).

The Zn alloys preferably include tin-zinc (Sn—Zn) alloy, bismuth-zinc (Bi—Zn) alloy or indium-zinc (In—Zn) alloy.

Preferably, the Sn—Zn alloy has Sn content of 30 to 99 wt. %, the Bi—Zn alloy has Bi content of 1 to 5 wt. % and the In—Zn alloy has In content of 15 to 99 wt. %.

In the heat treating step of the via formation method, thermal gradient is preferably applied in a direction perpendicular to the chips.

The via formation method preferably comprises the step of applying pressure during the heat treatment step.

The via formed using Zn and Zn alloys comprises a seed layer deposited inside the via hole formed in the chip and a plated layer formed on the seed layer by using Zn and Zn alloys.

The seed layer is preferably deposited with at least one selected from a metal group consisting of Au, Ni, Cu, Pt, Ag and Zn.

The process for fabrication of a three-dimensional multiple chip stack package according to the present invention comprises the steps of: polishing front and back sides of a chip having a via which was formed using Zn and Zn alloys; forming a bump layer on upper or lower side of the polished chip; laminating at least one polished chip in sequence on another polished chip after laminating the latter on a substrate which has a bottom metal layer through the bump layer and a solder, or otherwise, initially laminating multiple polished chips, each of which has the bump layer, in sequence, to form a chip package then laminating the chip package on a bottom metal layer of a substrate through a solder.

In the present invention, when at least one polished chip is laminated in sequence on top of another polished chip formed using Zn and Zn alloys after laminating a bump layer of the latter chip on a substrate having a bottom metal layer by a solder, Zn content of Zn alloys is preferably controlled according to the order for laminating the chips.

In the present invention, when at least one polished chip is laminated in sequence on top of another polished chip formed using Zn and Zn alloys after laminating a bump layer of the chip on a substrate having a bottom metal layer by a solder, the solder is preferably reflowed.

In the present invention, the solder used in the present invention is preferably lead (Pb) free solder.

In the present invention, the Pb free solder preferably includes at least one selected from a group consisting of Sn—Ag, Sn—Ag—Cu, Sn—Cu, Sn—Zn and Sn—Ag—Zn.

In the present invention, the bottom metal layer preferably contains at least one selected from a group consisting of Cu, Ni(P), Au and Cu OSP (organic solderability preservative).

In the present invention, the bump layer preferably contains at least one selected from a group consisting of Cu/Sn, Ni/Sn, Ni(P)/Sn and Zn.

### Advantageous Effects

According to the present invention, there is provided a process for fabrication of a three-dimensional chip stack package in which via holes of chips are filled with Zn and Zn alloys during lamination of three-dimensional chips, and which has advantages of: overcoming problems caused by Cu via such as long time consumption and difficulties in establishment of processing parameters; and solving problems in successive processes caused by Sn via or via formed using other low melting point metals, thereby improving reliability of the process.

Moreover, the present invention is effective to reduce processing time and cost by adopting direct current (DC) plating process and heat treatment of Zn and Zn alloys.

Also, the present invention is effective to produce a chip having via with desired thermal properties by controlling Zn content of Zn alloys.

### BRIEF DESCRIPTION OF THE DRAWINGS

The above objects, features and advantages of the present invention will become more apparent to those skilled in the related art in conjunction with the accompanying drawings. In the drawings:

FIGS. 1, 2, 3, 4 and 5 illustrate a process for formation of three-dimensional chip having via formed using Zn and Zn alloys according to a preferred embodiment of the present invention;

FIGS. 6 and 7 illustrate a process for fabrication of a three-dimensional multiple chip stack package comprising chips, each of which has via formed using Zn and Zn alloys according to a preferred embodiment of the present invention;

FIG. 8 shows a graph illustrating variation of melting points depending on Zn content of Sn—Zn alloy according to a preferred embodiment of the present invention;

FIG. 9 shows a photograph of a via hole with Zn deposited on an inside by an electroplating process according to a preferred embodiment of the present invention;

FIG. 10 shows a photograph of a via hole heat treated by reflowing in a hot furnace after Zn plating according to a preferred embodiment of the present invention; and

FIG. 11 shows a photograph of a via hole heat treated in a hot furnace after Zn plating and removing oxide film from surface of the plated via hole according to a preferred embodiment of the present invention.

### DESCRIPTION OF SYMBOLS FOR MAJOR PARTS IN DRAWINGS

100: silicon chip

110: via hole

120: seed layer

130: plated layer

200: substrate

210: bump layer

220: bottom metal layer

230: solder

### BEST MODE FOR CARRYING OUT THE INVENTION

Hereinafter, the present invention will be described in detail by the following embodiments with reference to the accompanying drawings.

With regard to constitutional elements indicated by numerical symbols in the drawings, the same element which was illustrated in one of the drawings, if possible, has the same symbol in other one(s). General constructions and functions commonly known in related arts are not essential components for the present invention and have not been described in detail herein, in order to avoid unnecessary duplication of explanation thereof.

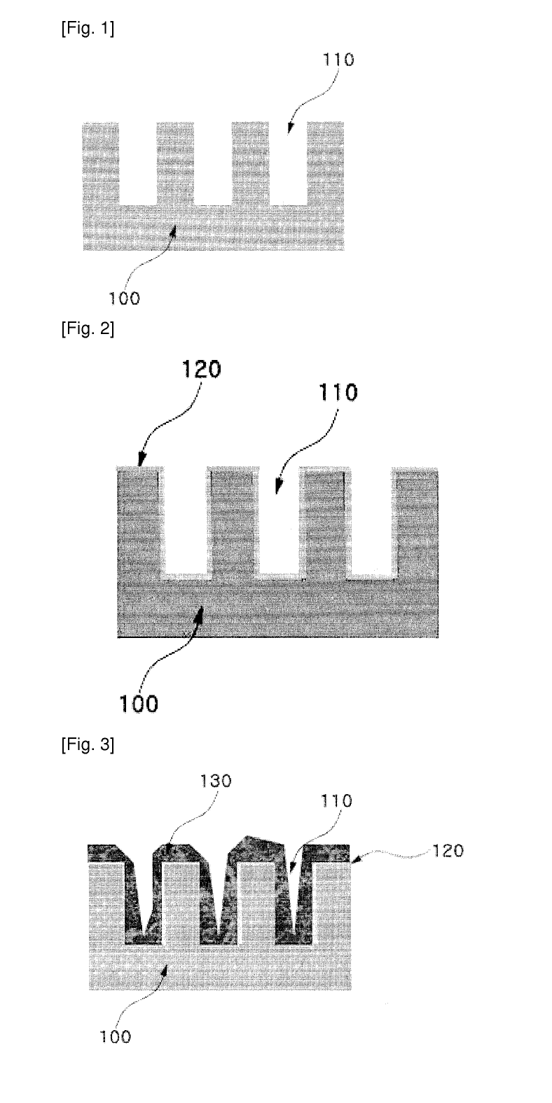

FIGS. 1, 2, 3, 4 and 5 illustrate a process for formation of three-dimensional chips having via formed using Zn and/or Zn alloys according to a preferred embodiment of the present invention.

Referring to FIG. 1, after forming via holes 110 on a silicon chip 100 through deep reactive ion etching or laser drilling, an insulation layer was deposited on the via holes by thermal oxidation of SiO₂.

Referring to FIG. 2, a seed layer 120 was deposited on a top portion of the chip formed as shown in FIG. 1 by sputtering or physical vapor deposition (PVD).

The seed layer is prepared by using at least one selected from a group consisting of Au, Ni, Cu, Pt, Ag and Zn, which is favorably wetted by Zn to efficiently flow Zn ingredient into the via holes 110 during hot heat treatment.

Referring to FIG. 3, a plated layer 130 was formed by introducing a specimen into a plating bath to prepare Zn alloys and plating a top portion of the seed layer 120 formed as shown in FIG. 2 with the prepared Zn alloys and Zn.

The plated layer 130 is formed by DC plating among electroplating processes and careful attention is required to prevent the via holes from being clogged during plating.

In case of using the prepared Zn alloys, a metal included in the Zn alloys is preferably selected from Sn, Bi, In and the like which form no intermetallic compounds with Zn ingredient.

When using Sn to prepare Sn—Zn alloy, the alloy can exhibit no formation of intermetallic compounds between Sn and Zn and have higher melting point above 300° C. if Sn content is more than 25 wt. %, so as to be affected little by successive processes in production of semiconductor chips.

When using Bi to prepare Bi—Zn alloy, the alloy has Bi content in the range of 1 to 5 wt. % and the melting point of 420 to 450° C. Likewise, when using In to prepare In—Zn alloy, the alloy has In content in the range of 15 to 99 wt. % and the melting point of 350 to 419° C. Both of the alloys can be affected little by successive processes in production of semiconductor chips.

Referring to FIG. 4, the via was completely formed by heat treatment to flow Zn and Zn alloys into the via holes after removing the oxide film from surface of the plated layer 130 shown in FIG. 3 by using an etching solution or a polishing process.

Removal of the oxide film assists in inhibition of voids possibly generated during fusion and solidification of Zn and Zn alloys. In order to inhibit generation of casting voids during solidification, the chips were heat treated in a hot furnace while forming thermal gradient in a direction perpendicular to the chips so as to start the solidification from lower portions of the via holes and remove the voids.

Zn and Zn alloys can be more rapidly and easily filled into the via holes by increasing pressure of upper portion of the specimen during heat treatment.

While heat treating the chips at a temperature of more than the melting point of Zn and Zn alloys, the via holes were fully filled with the Zn and Znc alloys, followed by slow cooling of the chips.

Referring to FIG. 5, after slowly cooling the chips of FIG. 4, thinning front and back sides of each of the chips having via through CMP (chemical mechanical polishing) process resulted in finally formed chips used for fabrication of chip stack packages.

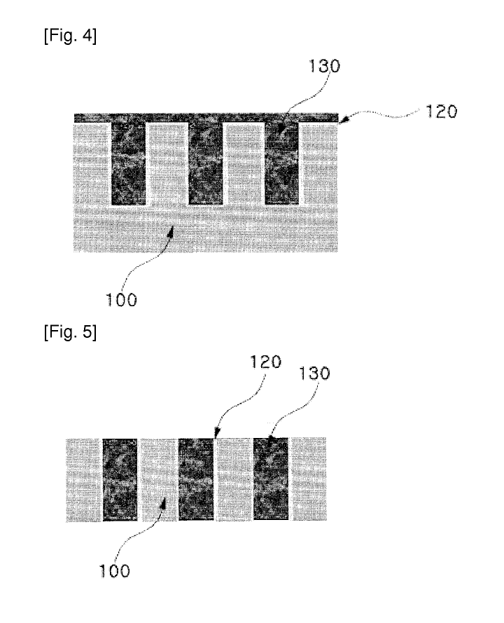

At least one chip stack package produced as shown in FIG. 5 is useable to fabricate a three-dimensional multiple chip stack package. A process for fabrication of the three-dimensional multiple chip stack package will be described with reference to the following FIGS. 6 and 7.

FIGS. 6 and 7 illustrate a process for fabrication of three-dimensional multiple chip stack package comprising chips, each of which has via formed using Zn and Zn alloys according to a preferred embodiment of the present invention.

Referring to FIG. 6, the process for fabrication of three-dimensional multiple chip stack package is implemented by using the chip having the via formed using Zn and Zn alloys as shown in FIG. 1, which includes the steps of: forming patterns by lithography to prepare a bump layer 210; sputtering a seed layer 120 for plating via portions; and electroplating the via portions.

The chips having the bump layers 210 were laminated on a substrate 200 having a bottom metal layer 220 by using a solder 230 and a reflowing process.

The bump layer 210 of the lowest chip layer in contact with the substrate 200 contains electroless nickel elements while the bump layers of the other chip layers contain one selected from Cu/Sn, Ni/Sn, Ni(P)/Sn and Zn.

The bottom metal layer 220 is in contact with the bump layer 210 and comprises Cu, Ni(P), Au and Cu OSP. The solder 230 is preferably Pb free solder and uses one selected from Sn—Ag, Sn—Ag—Cu, Sn—Cu, Sn—Zn, and Sn—Ag—Zn.

Next, the chips having the bump layers 210 on top portions thereof were laminated in sequence through the reflowing process at high temperature under pressure to fabricate a three-dimensional multiple chip stack package.

Herein, each of the chips laminated in sequence has the via with the plated layer 130 containing via formation material, that is, Zn alloys which are preferably selected by altering contents of constitutional elements in the alloys so as to have specific melting point suitable for the chips.

As an illustrative example, when higher melting point is required for upper layers further from the substrate, the melting point of Zn alloys as the via formation material is increased in phases by increasing relative content of Zn while going upper layers so as to form the desired three-dimensional multiple chip stack package in a short time.

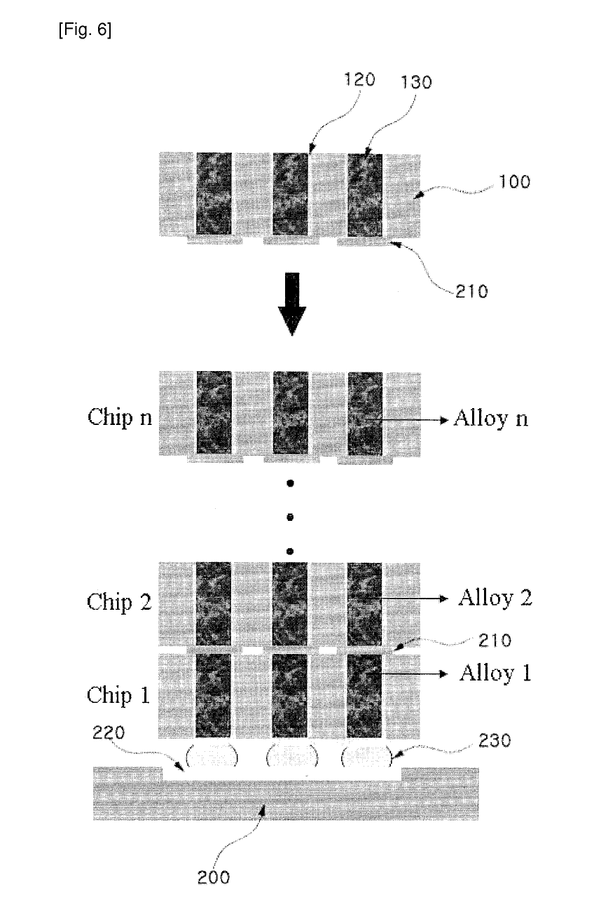

As a representative example of Zn alloys, Sn—Zn alloy has melting points and phase conditions varied by Sn content. Therefore, in order to fabricate a desired three-dimensional multiple chip stack package, via can be formed by altering Sn content (or amount of constitutional elements in the alloy) of via formation material in via of each of the chips laminated in sequence (see FIG. 8 and the following Table 1).

TABLE 1

| Zn content (wt. %) | Melting point (° C.) |
|---|---|
| 100 | 419.6 |
| 95 | 407 |
| 90 | 396.5 |
| 85 | 387 |
| 80 | 381 |
| 75 | 375 |
| 70 | 371 |
| 65 | 366 |
| 60 | 360 |
| 55 | 357 |
| 50 | 352 |
| 45 | 345 |
| 40 | 338 |

As illustrated in FIG. 7, after forming chips having bump layers 210 in the same manner as shown in FIG. 6, at least one chip may be laminated on another chip to fabricate a chip package, followed by lamination of at least one chip package in a desired sequence to complete a three-dimensional chip stack package.

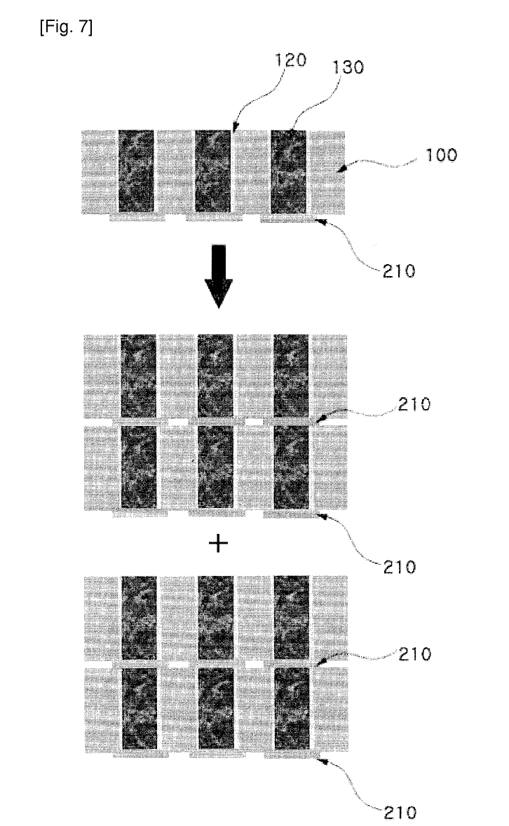

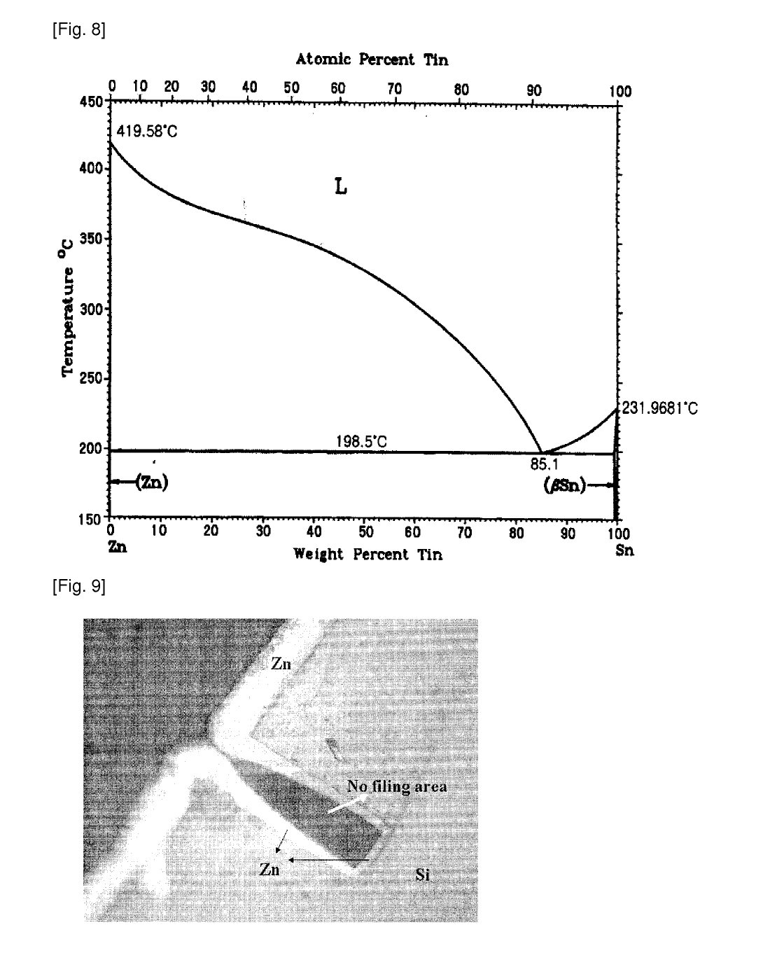

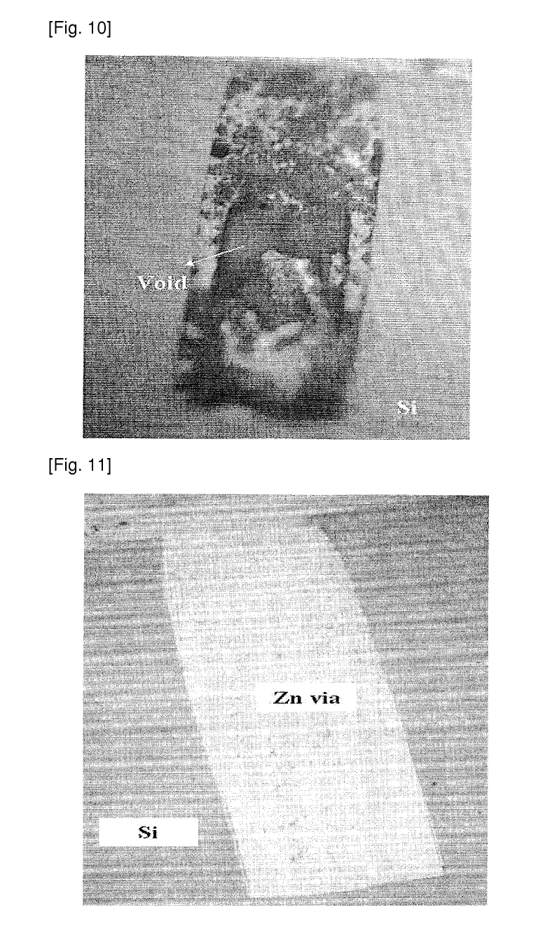

FIG. 9 shows a photograph of a via hole with Zn deposited on an inside by an electroplating process according to a preferred embodiment of the present invention; FIG. 10 shows a photograph of a via hole heat treated by reflowing in a hot furnace after Zn plating according to a preferred embodiment of the present invention; and FIG. 11 shows a photograph of a via hole heat treated in a hot furnace after Zn plating and removing oxide film from surface of the plated via hole according to a preferred embodiment of the present invention.

As similar to the via hole with Zn deposited on an inside by an electroplating process illustrated in FIG. 9, Cu via also exhibits a problem of defect in plating in that a lower portion of the via hole is not plated due to centralization of current density on entrance portion of the via hole as shown in FIG. 9.

However, Zn via has melting point lower than that of Cu via, so as to be filled with Zn by hot heat treatment.

Referring to FIG. 10, which is a photograph of a via hole heat treated by reflowing in a hot furnace after Zn plating to fill Zn in the via hole, Zn is molten by heat treatment immediately after plating thereby generating a lot of voids which, in turn, remain in Zn ingredient during solidification thereof causing a problem of forming via wirings with defects.

However, as shown in FIG. 11, if oxide film is removed from surface of the plated layer of the via hole before heat treatment of Zn plated via illustrated in FIG. 9, voids may be preferably prevented from remaining in Zn ingredient during fusion and solidification thereof.

### INDUSTRIAL APPLICATION

As described in detail above, the present invention provides via holes filled with Zn and Zn alloys, which are formed in chips useful for three-dimensional chip lamination process, so as to overcome problems of Cu via such as long processing time and difficulties in establishment of processing parameters and/or problems in successive processes caused by Sn via or via formed using other low melting point metals, thereby improving reliability of the process.

Moreover, the present invention is effective to reduce processing time and cost by adopting DC plating process and heat treatment of Zn and Zn alloys.

Also, the present invention is effective to produce chips having via with desired thermal properties by controlling Zn content of Zn alloys.

While the present invention has been described with reference to the accompanying drawings, it will be understood by those skilled in the art that various modifications and variations may be made therein without departing from the scope of the present invention as defined by the appended claims.

1. A method for formation of via comprising the steps of:
forming a seed layer inside a via hole; and
forming a plated layer on top of the seed layer, in which the plated layer is prepared using Zn and Zn alloys.

2. The method according to claim 1, further comprising the step of heat treating the plated layer after formation.

3. The method according to claim 1, wherein the seed layer is deposited with at least one selected from a metal group consisting of gold (Au), nickel (Ni), copper (Cu), platinum (Pt), silver (Ag) and zinc (Zn).

4. The method according to claim 1, wherein Zn alloys comprise tin-zinc (Sn—Zn) alloy, bismuth-zinc (Bi—Zn) alloy or indium-zinc (In—Zn) alloy.

5. The method according to claim 4, wherein the Sn—Zn alloy has Sn content of 30 to 99 wt. %, the Bi—Zn alloy has Bi content of 1 to 5 wt. % and the In—Zn alloy has In content of 15 to 99 wt. %.

6. The method according to claim 1, wherein the heat treating step further includes application of thermal gradient in a direction perpendicular to the chips.

7. The method according to claim 1, further comprising the step of applying pressure during the heat treatment step.

8. Via formed using Zn and Zn alloys comprising:
a seed layer deposited inside a via hole formed in a chip; and
a plated layer formed on top of the seed layer by using Zn and Zn alloys.

9. The via according to claim 8, wherein the seed layer is deposited with at least one selected from a metal group consisting of Au, Ni, Cu, Pt, Ag and Zn.

10. The via according to claim 8, wherein Zn alloys comprise tin-zinc (Sn—Zn) alloy, bismuth-zinc (Bi—Zn) alloy or indium-zinc (In—Zn) alloy.

11. The via according to claim 10, wherein the Sn—Zn alloy has Sn content of 30 to 99 wt. %, the Bi—Zn alloy has Bi content of 1 to 5 wt. % and the In—Zn alloy has In content of 15 to 99 wt. %.

12. A process for fabrication of a three-dimensional multiple chip stack package comprising the steps of:
polishing front and back sides of a chip having a via which was formed using Zn and Zn alloys according to the method as defined in claim 1;
forming a bump layer on upper or lower side of the polished chip; and
laminating at least one polished chip in sequence on another polished chip after laminating the latter on a substrate which has a bottom metal layer through the bump layer and a solder, or otherwise, initially laminating multiple polished chips, each of which has the bump layer, in sequence to form a chip package then laminating the chip package on a bottom metal layer of a substrate through a solder.

13. The process according to claim 12, wherein, when at least one polished chip is laminated in sequence on top of another polished chip formed using Zn and Zn alloys after laminating the bump layer of the latter chip on the substrate having the bottom metal layer by the solder, Zn content of Zn alloys is controlled according to the order for laminating the chips.

14. The process according to claim 12, wherein, when at least one polished chip is laminated in sequence on top of another polished chip formed using Zn and Zn alloys after laminating the bump layer of the latter chip on the substrate having the bottom metal layer by the solder, the solder is reflowed.

15. The process according to claim 12, wherein the solder is lead (Pb) free solder.

16. The process according to claim 15, wherein the Pb free solder includes at least one selected from a group consisting of Sn—Ag, Sn—Ag—Cu, Sn—Cu, Sn—Zn and Sn—Ag—Zn.

17. The process according to claim 12, wherein the bottom metal layer contains at least one selected from a group consisting of Cu, Ni(P), Au and Cu OSP.

18. The process according to claim 12, wherein the bump layer contains at least one selected from a group consisting of Cu/Sn, Ni/Sn, Ni(P)/Sn and Zn.
